(19) United States
(12) Patent Application Publication
(10) Pub. No.: US 2011/0212323 A1
(43) Pub. Date: Sep. 1, 2011

(54) METHOD FOR PREPARING OXIDE THIN FILM GAS SENSORS WITH HIGH SENSITIVITY

(75) Inventors: Ho Won Jang, Daegu (KR); Seok-Jin Yoon, Seoul (KR); Jin Sang Kim, Seoul (KR); Chong Yun Kang, Seoul (KR); Ji-Won Choi, Seoul (KR); Hi Gyu Moon, Pyeongtaek-si (KR)

(73) Assignee: Korea Institute of Science and Technology

(21) Appl. No.: 12/874,135

(22) Filed: Sep. 1, 2010

(30) Foreign Application Priority Data
Feb. 26, 2010 (KR) 10-2010-0017988
Mar. 30, 2010 (KR) 10-2010-0028684

(51) Int. Cl. B32B 5/16; B05D 3/00; B05D 3/12; B05D 3/06; C23C 14/34; B29D 7/01

(52) U.S. Cl. 428/327; 427/299; 427/535; 427/240; 427/551; 204/192.1; 264/214

(57) ABSTRACT

The present invention relates to a method for preparing oxide thin films with high sensitivity and reliability, which can be advantageously used in the fabrication of articles such as gas sensors. The present invention establishes a high reliability process for preparing large area microsphere templates which may be applicable to silicone semiconductor processes by simple plasma surface treatment and spin coating. The present invention achieves remarkably enhanced sensitivities of thin films of gas sensors by controlling the nanostructure shapes of hollow hemisphere oxide thin films by using simple plasma treatment. In particular, the gas sensor based on the nanostructured TiO₂ hollow hemisphere according to the present invention exhibits higher sensitivity, faster response and recovery speed to CO gas over conventional TiO₂ gas sensors.

The present application claims priority to Korean Patent Application No. 10-2010-0017988, filed Feb. 26, 2010, and Korean Patent Application No. 10-2010-0028684, filed Mar. 30, 2010, the subject matters of which are incorporated herein by reference in their entireties.

### FIELD OF THE INVENTION

The present invention relates to methods for preparing oxide thin films with high sensitivity and reliability, which can be advantageously used in the fabrication of articles, such as gas sensors.

### BACKGROUND OF THE INVENTION

It is highly expected that oxide thin film gas sensors can substitute other types of gas sensors due to their advantages, such as simple operation, low operating voltage and small volume. However, the decreased sensitivity attributable to thinned sensing layers has been an obstacle for the compatibilization of oxide thin film gas sensors. In order to enhance the sensitivities of oxide thin film gas sensors, a great deal of research has been carried out on changing the shape of the sensing materials, i.e., oxide thin films, from 2-dimensional planes to 3-dimensional nanostructures. Recently, there have been reports on studies where the sensitivities of gas sensors were enhanced by preparing 3-dimensional structured oxide thin films with hollow hemisphere shapes using polymer microspheres and applying the obtained oxide thin films to gas sensors (see [I. D. Kim, A. Rothschild, T. Hyodo and H. L. Tuller, Nano Lett. 6, 193 (2006)]; [I. D. Kim, A. Rothschild, D. J. Yang and H. L. Tuller, Sens. Actuators B 130, 9 (2008)]; and [Y. E. Chang, D. Y. Youn, G Ankonina, D. J. Yang, H. G. Kim, A Rothschild and I. D. Kim, Chem. Commun. 4019 (2009)]).

However, the biggest problem that has to be solved in preparing the above hollow hemisphere shaped ceramic thin films with a 3-dimensional structure by using polymer microspheres is that high reliability processes which may be applicable to conventional silicone semiconductor processes have not yet been developed. For example, it is difficult to obtain uniform polymer microsphere templates even on areas (typically mm²-scale) corresponding to sensing films of gas sensors. Thus, in order to ensure reliability and form reproducible oxide sensing films, there is an urgent need to develop methods for preparing thin films which are applicable to large-area silicone wafer processes.

Further, gas sensors based on 3-dimensional structured oxide thin films with hollow hemisphere shapes, which are prepared by using polymer microspheres, exhibit 2 to 4 times higher sensitivities, as compared with conventional flat thin film gas sensors, since the surface areas of 3-dimensional structured oxide thin films with hollow hemisphere shapes are 2 to 4 times larger than those of flat thin films. Thus, the increase in surface area results in an enhancement of sensitivity. However, in order for the hollow hemisphere shaped oxide thin film gas sensors to be used in high sensitivity harmful-air filtration systems or environment monitoring systems, the sensitivity enhancement needs to be greater than the 2 to 4 times higher sensitivity over flat thin film gas sensors.

Thus, the present invention establishes a high reliability process for preparing large-area microsphere templates which may be applicable to silicone semiconductor processes by simple plasma surface treatment and spin coating. Further, the present invention achieves remarkably enhanced sensitivities of thin films of gas sensors by controlling the nanostructure shapes of hollow hemisphere oxide thin films by using simple plasma treatment.

### SUMMARY OF THE INVENTION

The present invention relates to a method for preparing a 3-dimensional structured oxide thin film. The method first involves treating a surface of a substrate. Next, a colloidal solution of polymer microspheres is applied on the surface of the substrate to obtain a polymer microsphere monolayer template. Then, an oxide thin film is deposited on the polymer microsphere monolayer template.

The present invention also relates to a method for preparing a nanostructured oxide thin film. The method first involves treating a surface of a substrate. Next, a colloidal solution of polymer microspheres is applied on the surface of the substrate to obtain a polymer microsphere monolayer template. Then, the polymer microsphere template is subjected to plasma treatment to form a nanostructured polymer microsphere network. Finally, an oxide thin film is deposited on the nanostructured polymer microsphere network.

Another aspect of the present invention relates to a 3-dimensional structured oxide thin film prepared by the above methods.

The present invention also relates to an article prepared by using the above 3-dimensional structured oxide thin film.

In addition to the aspects and features described above, further aspects and features of the present invention will become apparent from the following description of illustrative embodiments provided in conjunction with the accompanying drawings.

### BRIEF DESCRIPTION OF THE DRAWINGS

FIG. 1 is a schematic diagram showing the process for preparing a 3-dimensional structured oxide thin film with a hollow hemisphere shape in accordance with the present invention.

FIG. 2 is a plan-view scanning electron microscope (SEM) image of the microsphere template obtained by conventional techniques (e.g., droplet deposition).

FIG. 3 is a photograph showing the changes in contact angles by surface treatment, and a plan-view SEM image showing the microsphere distribution.

FIGS. 4(a)-(b) are (a) plan-view and (b) side-view SEM images showing the large area template with a monolayer of uniformly distributed microspheres in accordance with the present invention.

FIGS. 5(a)-(b) are (a) plan-view and (b) side-view SEM images showing the large area 3-dimensional structured thin film of uniformly distributed TiO₂ hollow hemispheres in accordance with the present invention.

FIGS. 6(a)-(b) are (a) a photograph of a 3-dimensional structured TiO₂ thin film gas sensor and (b) a graph showing the responses of the 2-dimensional flat structured and 3-dimensional hollow hemisphere structured TiO₂ thin film gas sensors to CO gas.

FIG. 7 is a graph comparing the sensitivities of the gas sensor based on the 3-dimensional structured thin film of TiO₂ hollow hemispheres with those of conventional gas sensors based on TiO₂ nanostructures.

FIG. 8 is a graph showing the reaction and response speeds of the 3-dimensional structured TiO₂ thin film gas sensor prepared in accordance with the present invention to 50 ppm of CO gas.

FIG. 9 is a schematic diagram showing a process for preparing a thin film of nanostructured oxide hollow hemispheres.

FIG. 10 shows plan-view and side-view SEM images illustrating the changes in shapes of the polymer microsphere template by oxygen plasma treatment.

FIG. 11 shows plan-view and side-view SEM images of the thin films of plain TiO₂, TiO₂ hollow hemispheres (THH) and nanostructured THH.

FIG. 12 is an X-ray diffraction pattern of the thin films of plain TiO₂, THH and nanostructured THH.

FIGS. 13(a)-(b) are (a) a response curve against 1-500 ppm of CO gas and (b) a graph showing the sensitivities versus CO gas concentrations of the gas sensors based on thin films of plain TiO₂, THH and nanostructured THH at 250° C. The image inserted in FIG. 13(a) is a plan-view SEM image showing the film of nanostructured THH formed on a Pt interdigitated electrode (IDE) pattern.

FIG. 14 is a graph comparing the sensitivities of the gas sensor based on thin film of nanostructured THH prepared in accordance with the present invention with those of the gas sensors based on conventional TiO₂ nanostructures.

### DETAILED DESCRIPTION OF THE INVENTION

The polymer microspheres that can be used in preparing gas sensors according to the present invention may be composed of one or more selected from the group consisting of polystyrene (PS), poly(methyl methacrylate) (PMMA) and polyethylene (PE), have diameters ranging from 10 nm to 1000 nm, and exist in colloidal states where polymer microspheres are dispersed in water, a basic or acidic aqueous solution with weight ratios of 0.1% to 10%. In one embodiment of the present invention, the surfaces of polymer microspheres may be neutral or converted with surface groups such as —COOH or —NH₂. Before the colloidal solution is spin coated on the silicone substrate, the substrate surface may be subject to plasma treatment with one or more selected from the group consisting of oxygen, argon, nitrogen and hydrogen plasmas to make it hydrophilic. In order to maximize the hydrophilicity of the surface, high power oxygen plasma may be used. Right after the plasma surface treatment, the microsphere monolayer template where microspheres are highly filled and uniformly distributed in a large area may be obtained by a spin coating process.

Hollow hemisphere shaped oxide thin films may be obtained by depositing an oxide thin film on a template with a monolayer of polymer microspheres using sputtering, electron beam deposition or thermal deposition, and then removing the polymer microspheres through heat treatment at 400-700° C. The crystallinity of the oxide thin film is also enhanced by the above heat treatment. The oxide thin film may include one or more selected from the group consisting of Ti, V, Cr, Mn, Fe, Co, Ni, Cu, Zn, Ga, Al, Nb, Mo, Cd, In, Sn, Sb, Ta and W.

The above method has advantages in that the process is simple and reliability can be ensured, since large area 3-dimensional structured oxide thin film gas sensors may be prepared by forming a hollow hemisphere shaped oxide thin film on a SiO₂/Si substrate, onto which a Pt IDE pattern is formed.

In the meantime, after the microsphere monolayer template, where microspheres are highly filled and uniformly distributed, is obtained through a spin coating process right after plasma treatment of the substrate surface, if the above microsphere monolayer is treated again with oxygen plasma, the polymer microspheres are etched. If the oxygen plasma treatment time is controlled at the lowest power possible, a nanostructured microsphere network where microspheres share nanobridges is formed. This plasma treatment may be performed using one or more selected from the group consisting of oxygen, argon, nitrogen, hydrogen, SF₆ and Cl₂.

An oxide thin film may be deposited on the above nanostructured microsphere network by sputtering, electron beam deposition or thermal deposition, followed by heat treatment at 400-700° C. to remove the polymer microspheres, resulting in an oxide thin film with a nanostructured hollow hemisphere shape. The crystallinity of the oxide thin film is also enhanced by the above heat treatment, as mentioned above.

According to the above method, oxide thin film gas sensors with remarkably enhanced sensitivities may be prepared by forming the oxide thin film with a nanostructured hollow hemisphere shape on a SiO₂/Si substrate, onto which a Pt IDE pattern is formed.

The nanostructured oxide hollow hemisphere thin film may also include one or more selected from the group consisting of Ti, V, Cr, Mn, Fe, Co, Ni, Cu, Zn, Ga, Al, Nb, Mo, Cd, In, Sn, Sb, Ta and W.

Hereinafter, various embodiments of the present invention will be described in detail by referring to the accompanying drawings attached hereto. However, detailed descriptions of well-known functions and configurations will be omitted in the following description.

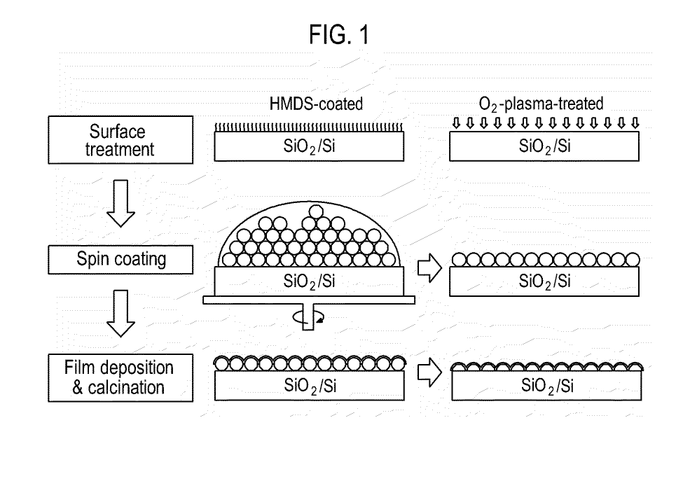

FIG. 1 is a schematic diagram showing a process for preparing a 3-dimensional structured oxide thin film with high surface and reliability in accordance with the present invention, and reveals that the hollow hemisphere shaped oxide thin film can be obtained by coating hexamethyldisilazane (HMDS) on a SiO₂/Si substrate or treating the substrate with oxygen plasma, and then spin coating a colloidal solution of microspheres on the surface to obtain a microsphere monolayer template, followed by sputtering deposition at room temperature and heat treatment at 550° C.

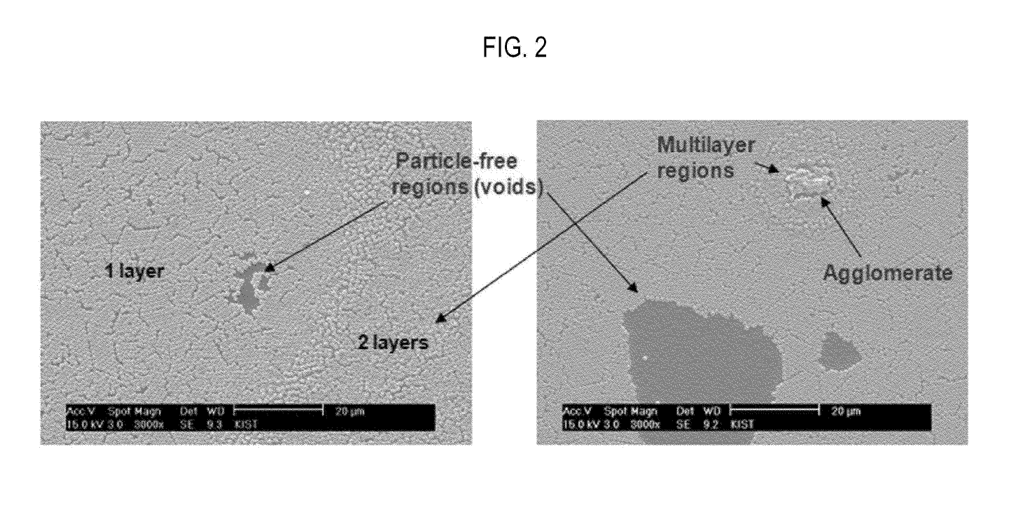

FIG. 2 is a scanning electron microscope (SEM) image showing a typical surface shape of the microsphere template which is formed by conventional technique (droplet deposition) and exhibits problems such as particle-free regions (voids), multilayer regions and agglomerates.

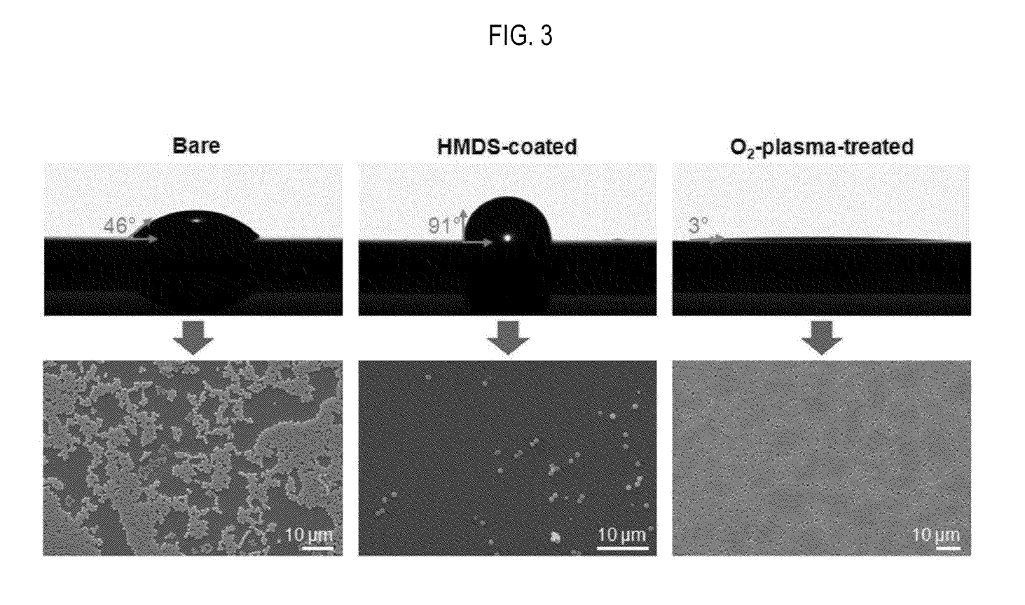

FIG. 3 is a photograph showing the contact angles between water drops on untreated, HMDS-coated and oxygen plasma-treated substrates and the above substrates, and SEM images showing the surface shapes of templates obtained after the above three substrates are spin coated with the microspheres. As confirmed by FIG. 3, a template with a filled monolayer of microspheres can be obtained, since the adhesion between the substrate surface and microspheres can be enhanced if hydrophilic surfaces are obtained through oxygen plasma treatment.

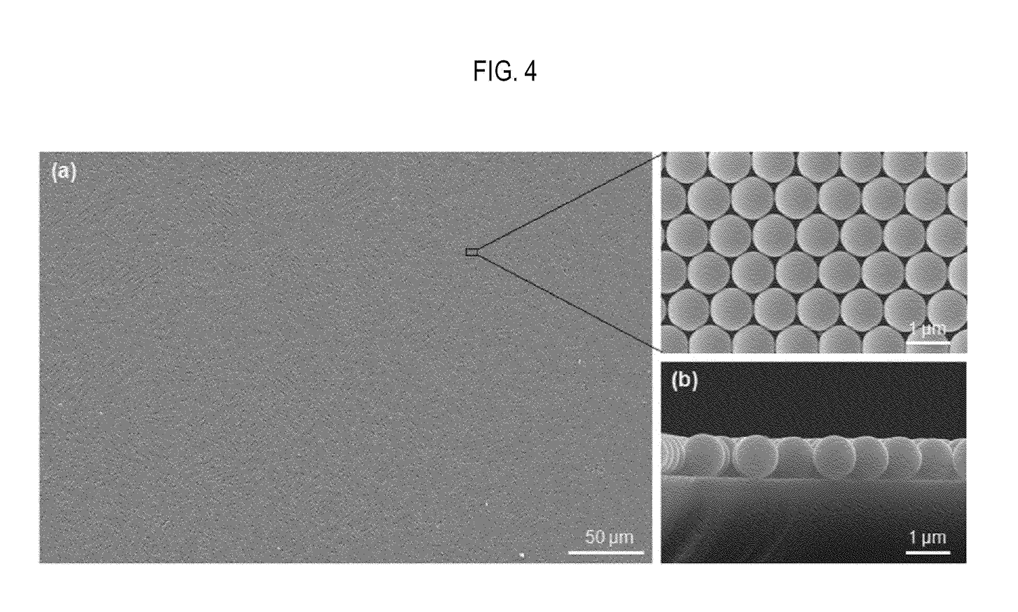

FIG. 4 shows plan-view and side-view SEM images of the large area template with a monolayer of microspheres (diameters of about 1000 nm) obtained by using oxygen plasma surface treatment and spin coating. FIG. 4 shows that problems such as microsphere-free regions, multilayer regions and agglomerates are not observed in the large area of 250×400 μm².

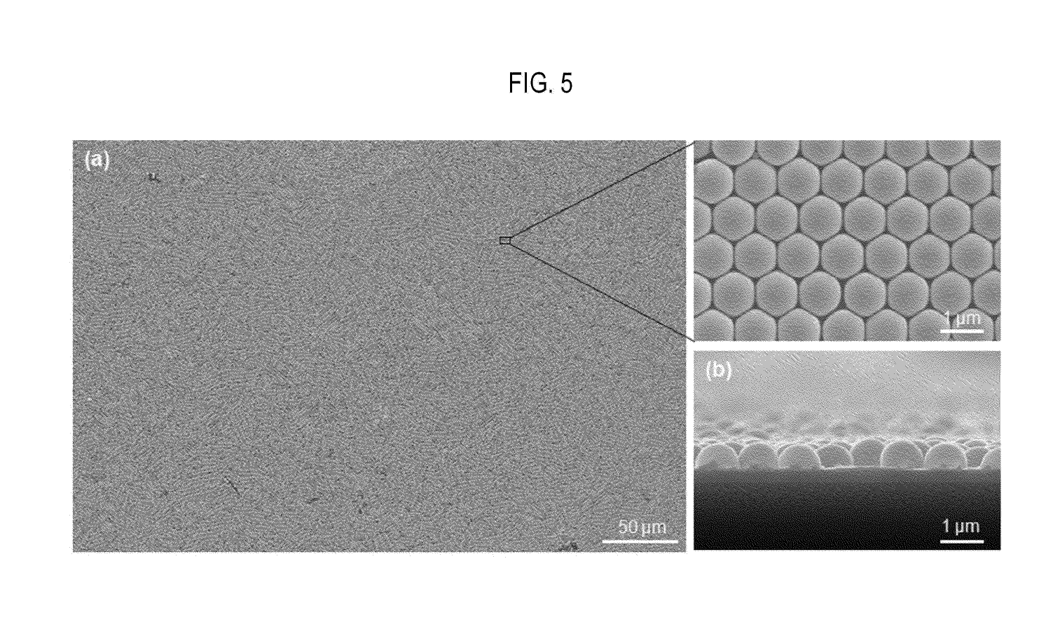

FIG. 5 shows plan-view and side-view SEM images of the large area thin film of TiO₂ hollow hemispheres (THH) prepared by using a large area microsphere monolayer template.

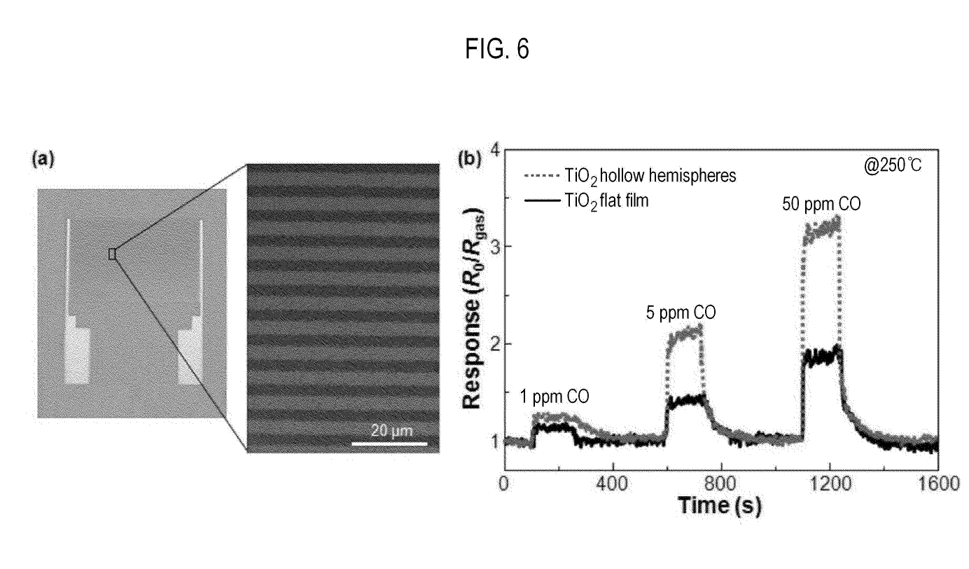

FIG. 6 shows a photograph depicting a TiO₂ thin film gas sensor prepared by forming a hollow hemisphere shaped TiO₂ thin film on a Pt IDE pattern with 5 μm intervals, and a graph showing the working properties of sensors at 250° C. towards 1-50 ppm of CO gas. As shown in FIG. 6, the 3-dimensional structured thin film gas sensor of the present invention exhibits higher sensitivities, as compared with the 2-dimensional flat thin film gas sensor.

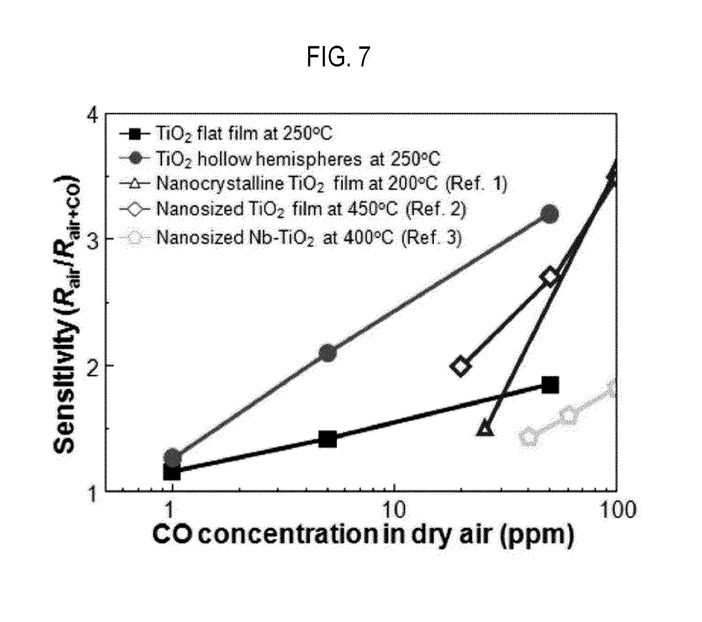

FIG. 7 is a graph showing the changes in sensitivities of gas sensors versus CO gas concentrations. FIG. 7 reveals that the TiO₂ hollow hemisphere gas sensor of the present invention shows higher sensitivities toward CO gas of a low concentration over conventional TiO₂ gas sensors (see Ref. 1: [M. R. Mohammadi, D. J. Fray and M. Ghorbani, Solid State Sci. 10, 884 (2008)]; Ref. 2: [V. Guidi, M. C. Carotta, M. Ferroni, G. Martinelli, L. Paglialonga, E. Comini and G. Sberveglieri, Sens. Actuators B 57, 197 (1999)]; and Ref. 3: [A. Rothschild, Y. Komem, A. Levakov, N. Ashkenasy and Yoram Shapira, Appl. Phys. Lett. 82, 574 (2003)]).

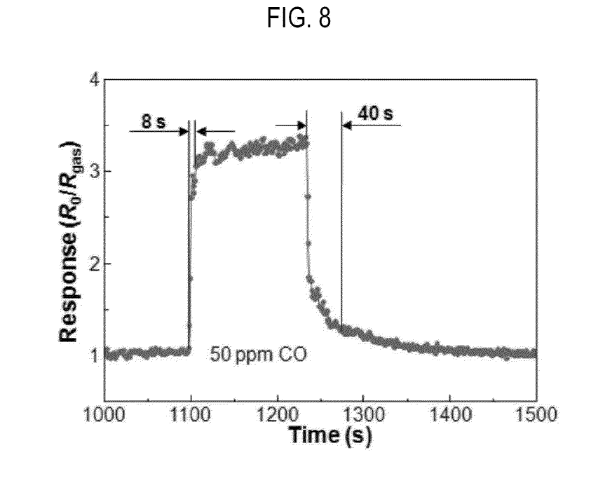

FIG. 8 shows a 90% change in response and recovery speeds of reacting against 50 ppm of CO gas for the TiO₂ hollow hemisphere gas sensor of the present invention. In this regard, the response time of 8 seconds is a very fast response speed value, as compared with the responses times (usually, from 1 minute to 5 minutes) of conventional TiO₂ gas sensors (see Ref. 1: [M. R. Mohammadi, D. J. Fray and M. Ghorbani, Solid State Sci. 10, 884 (2008)]; Ref. 2: [V. Guidi, M. C. Carotta, M. Ferroni, G. Martinelli, L. Paglialonga, E. Comini and G. Sberveglieri, Sens. Actuators B 57, 197 (1999)]; Ref. 3: [A. Rothschild, Y. Komem, A. Levakov, N. Ashkenasy and Yoram Shapira, Appl. Phys. Lett. 82, 574 (2003)]; Ref. 4: [Z. Seeley, Y. J. Choi and S. Bose, Sens. Actuators B 140, 98 (2009)]; and Ref. 5: [O. Landau, A. Rothschild and E. Zussman, Chem. Mater. 21, 9 (2009)]).

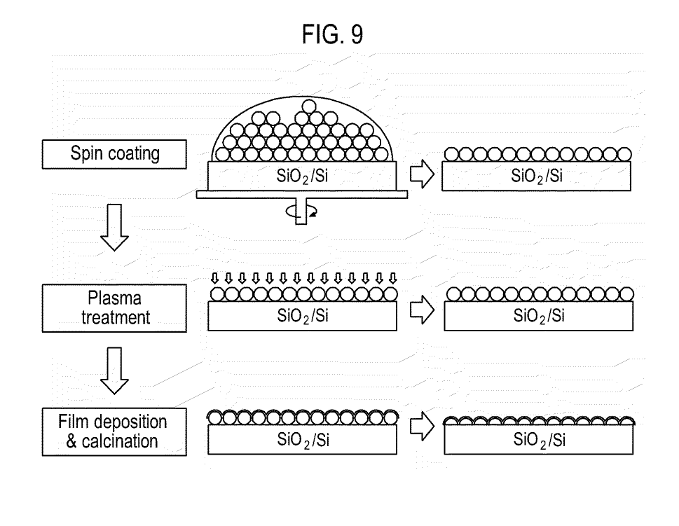

FIG. 9 is a schematic diagram showing the process for preparing an oxide thin film with a nanostructured hollow hemisphere shape in accordance with the present invention. The thin film of nanostructured oxide hollow hemispheres can be obtained by spin coating a colloidal solution of microspheres on a SiO₂/Si substrate to obtain a template with highly filled monolayer of microspheres, and then subjecting it to oxygen plasma treatment to form nanobridges, followed by sputtering deposition at room temperature and heat treatment at 550° C.

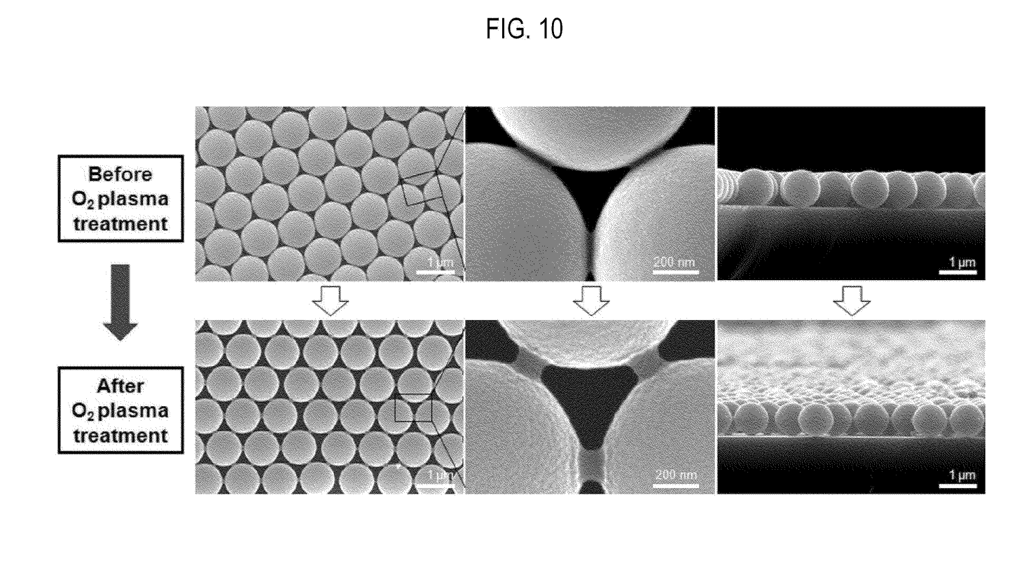

FIG. 10 is plane-view and side-view SEM images showing the changes in shapes of the microsphere template before and after oxygen plasma treatment. After oxygen plasma treatment, the structure of microspheres is changed to the network structure that is connected with nanobridges having widths of 100 nm or less.

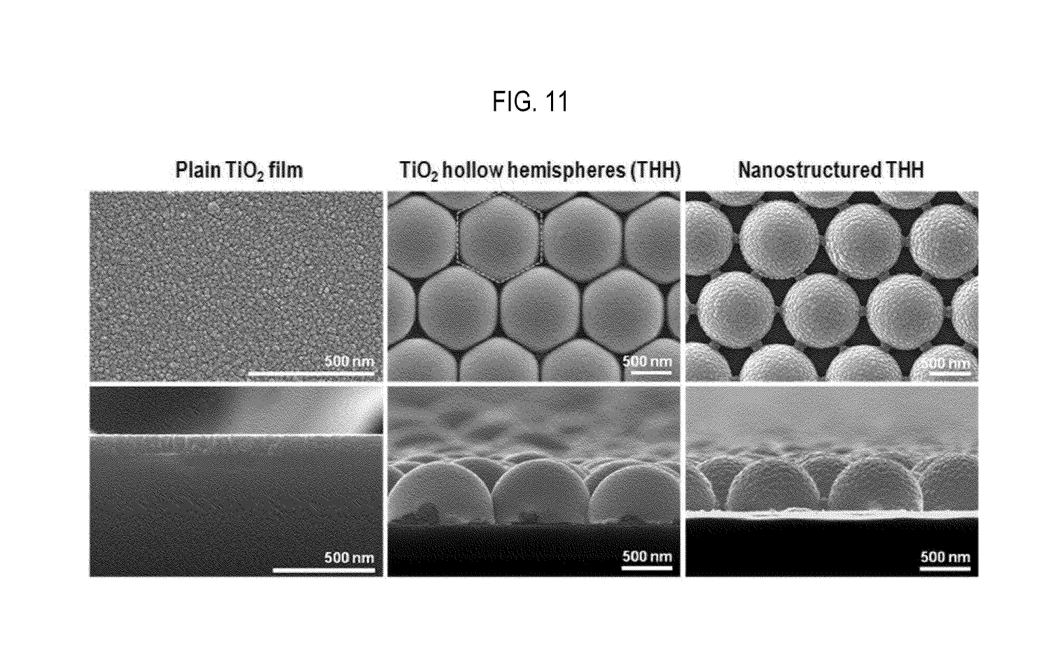

FIG. 11 is plan-view and side-view SEM images of the 100 nm thick thin films of plain TiO₂, TiO₂ hollow hemispheres (THH) (prepared by using a microsphere template not subjected to oxygen plasma treatment), and nanostructured THH (prepared on a microsphere template via oxygen plasma treatment). It can be confirmed from FIG. 11 that the nanobridges between the microspheres, which have been formed after the oxygen plasma treatment, still exist even after thin film deposition and heat treatment, forming the TiO₂ hollow hemisphere thin film with a nanobridge network shape. It is noticeable in that the shapes of the individual cells in the nanostructured hollow hemisphere thin film are a perfect circle, when viewed from a plane parallel to the film, whereas the shapes of the individual cells in the hollow hemisphere thin film are close to a hexagon.

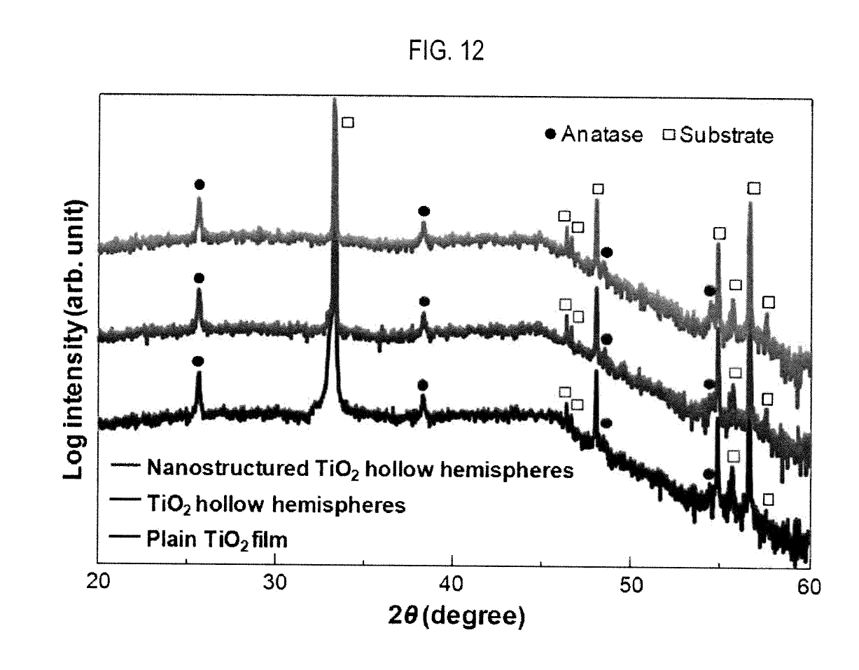

FIG. 12 illustrates results from an X-ray diffraction analysis of the three shapes of TiO₂ thin films (plain, hollow hemisphere and nanostructured hollow hemisphere). All of the above three thin films exist as anatase phases and have no differences in terms of crystallinities or crystallite sizes. That is, it is shown that the shapes of thin films have no effect on the crystallinities of thin films.

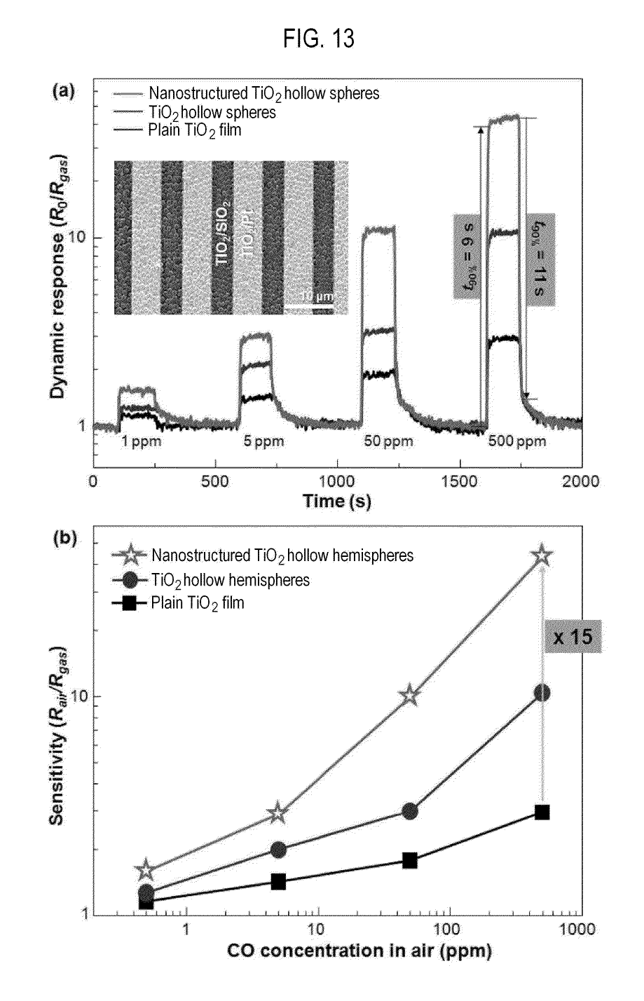

FIG. 13 shows graphs illustrating the working properties towards 1-500 ppm of CO gas and the sensitivities versus CO concentrations at 250° C. of gas sensors based on the thin films of plain TiO₂, THH and nanostructured THH, which were fabricated using SiO₂/Si substrates onto which a Pt IDE pattern with 5 μm intervals is formed. As confirmed by FIG. 13, the sensor based on a nanostructured hollow hemisphere thin film exhibits the greatest sensitivity over the sensors based on plain or hollow hemisphere thin films. In particular, the nanostructured hollow hemisphere thin film gas sensor shows 15 times higher sensitivity towards 500 ppm of CO gas, as compared with the plain thin film sensor. In addition, the nanostructured thin film sensor shows fast reaction/response times of about 10 seconds, which is the fastest speed value compared to the reaction/response times (usually, about from 30 seconds to 5 minutes) of conventional oxide gas sensors (see [G. Eranna, B. C. Joshi, D. P. Runthala and R. P. Gupta, Oxide materials for development of integrated gas sensors—a comprehensive review, Crit. Rev. Solid State Mater. Sci. 29 (2004) 111-188]).

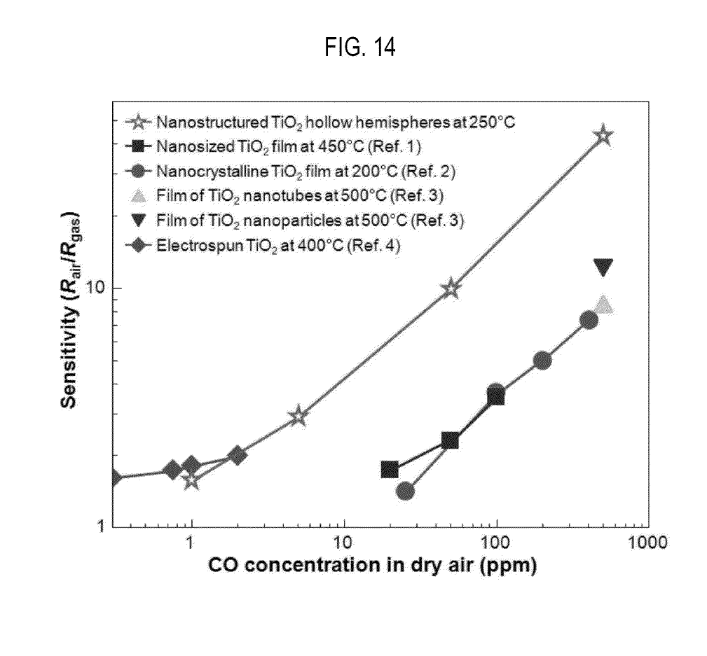

FIG. 14 is a graph comparing the sensitivities of the gas sensor based on thin film of nanostructured TiO₂ hollow hemispheres according to the present invention with those of gas sensors based on conventional TiO₂ nanostructures towards CO gas. As confirmed by FIG. 14, the gas sensor of the present invention shows higher sensitivities over conventional TiO₂ nanostructure gas sensors and shows the highest level sensitivities even towards 1 ppm or less of CO gas (see Ref 1: [V. Guidi, M. C. Carotta, M. Ferroni, G. Martinelli, L. Paglialonga, E. Comini and G. Sberveglieri, Preparation of nanosized titania thick and thin films as gas-sensors, Sens. Actuators B 57 (1999) 197-200]; Ref. 2: [M. R. Mohammadi, D. J. Fray and M. Ghorbani, Comparison of single and binary oxide sol-gel gas sensors based on titania, Solid State Sci. 10 (2008) 884-893]; Ref 3: [M. H. Seo, M. Yuasa, T. Kida, J. S. Huh, K. Shimanoe and N. Yamazoe, Gas sensing characteristics and porosity control of nanostructured films composed of TiO₂ nanotubes, Sens. Actuators B 137 (2009) 513-520]; and Ref. 4: [O. Landau, A. Rothschild and E. Zussman, processing-microstructure-properties correlation of ultrasensitive gas sensors produced by electrospinning, Chem. Mater. 21 (2009) 9-11]).

As mentioned above, according to the present invention, higher gas sensitivities and faster response speeds compared to conventional gas sensors may be achieved.

The method for preparing high sensitivity oxide thin film gas sensors of the present invention has a simple fabrication process and may be applicable to large area silicone semiconductor processes, and thus, has a high compatibilization potential in terms of performance and the competitive cost of gas sensors. In particular, gas sensors according to the present invention have the highest level sensitivities and fast reaction/response times towards CO gas, and therefore, can be advantageously used in air quality systems (AQS) for automotives. Meanwhile, the method for preparing nanostructured hollow hemisphere thin films according to the present invention may be used very easily in areas of coating electrodes or surfaces of gas sensors, as well as dye-sensitized solar cells, water purification units, lithium secondary batteries, actuators, energy harvesters, and semiconductor solar cells.

While the present invention has been described and illustrated with respect to a number of embodiments of the invention, it will be apparent to those skilled in the art that variations and modifications are possible without deviating from the broad principles and teachings of the present invention, which is defined by the claims appended hereto.

What is claimed:

1. A method for preparing a 3-dimensional structured oxide thin film comprising:
treating a surface of a substrate;
applying a colloidal solution of polymer microspheres on the surface of the substrate to obtain a polymer microsphere monolayer template; and
depositing an oxide thin film on the polymer microsphere monolayer template.

2. The method of claim 1, wherein the treating a surface of the substrate is carried out by using one or more selected from the group consisting of oxygen, argon, nitrogen and hydrogen plasmas under conditions effective to render the surface of the substrate hydrophilic.

3. The method of claim 1, wherein the polymer microspheres are composed of one or more selected from the group consisting of polystyrene (PS), poly(methyl methacrylate) (PMMA) and polyethylene (PE), and have diameters ranging from 10 nm to 1000 nm.

4. The method of claim 1, wherein the surfaces of the polymer microspheres are neutral or converted with surface groups selected from the group consisting of —COOH and —NH₂.

5. The method of claim 1, wherein the applying a colloidal solution of polymer microspheres is carried out by spin coating.

6. The method of claim 1, wherein the depositing an oxide thin film is carried out by one or more techniques selected from the group consisting of room temperature sputtering, electron beam deposition and thermal deposition.

7. The method of claim 1, further comprising:
removing the polymer microsphere monolayer template from the oxide thin film, after the depositing, by heat treatment at 400° C. to 700° C., to obtain a thin film of 3-dimensional structured oxide hollow hemisphere shapes.

8. The method of claim 1, wherein the oxide thin film includes one or more selected from the group consisting of Ti, V, Cr, Mn, Fe, Co, Ni, Cu, Zn, Ga, Al, Nb, Mo, Cd, In, Sn, Sb, Ta and W.

9. A method for preparing a nanostructured oxide thin film comprising:
treating a surface of a substrate;
applying a colloidal solution of polymer microspheres on the surface of the substrate to obtain a polymer microsphere monolayer template;
subjecting the polymer microsphere template to plasma treatment to form a nanostructured polymer microsphere network; and
depositing an oxide thin film on the nanostructured polymer microsphere network.

10. The method of claim 9, further comprising:
removing the nanostructured polymer microsphere network from the oxide thin film to obtain a thin film of nanostructured oxide hollow hemispheres.

11. The method of claim 9, wherein the subjecting the polymer microsphere template to plasma treatment is carried out by using one or more selected from the group consisting of oxygen, argon, nitrogen, SF₆ and Cl₂.

12. The method of claim 9, wherein the polymer microspheres are composed of one or more selected from the group consisting of polystyrene (PS), poly(methyl methacrylate) (PMMA) and polyethylene (PE), and have diameters ranging from 10 nm to 1000 nm.

13. The method of claim 9, wherein the oxide thin film includes one or more selected from the group consisting of Ti, V, Cr, Mn, Fe, Co, Ni, Cu, Zn, Ga, Al, Nb, Mo, Cd, In, Sn, Sb, Ta and W.

14. The method of claim 9, wherein the oxide thin film is formed by room temperature sputtering, electron beam deposition or thermal deposition.

15. The method of claim 10, wherein the removing the nanostructured polymer microsphere network is performed by heat treatment.

16. The method of claim 15, wherein the heat treatment is carried out under conditions effective to enhance the crystallinity of the oxide thin film.

17. An oxide thin film prepared according to the method of claim 1.

18. An article prepared by using the oxide thin film of claim 17.

19. The article of claim 18, wherein the article is selected from the group consisting of gas sensors, dye-sensitized solar cells, water purification units, lithium secondary batteries, semiconductor solar cells, actuators and energy harvesters.

20. An oxide thin film prepared according to the method of claim 9.

21. An article prepared by using the oxide thin film of claim 20.

22. The article of claim 21, wherein the article is selected from the group consisting of gas sensors, dye-sensitized solar cells, water purification units, lithium secondary batteries, semiconductor solar cells, actuators and energy harvesters.

23. The method of claim 6, further comprising:
removing the polymer microsphere monolayer template from the oxide thin film, after the depositing, by heat treatment at 400° C. to 700° C., to obtain a thin film of 3-dimensional structured oxide hollow hemisphere shapes.

24. The method of claim 6, wherein the oxide thin film includes one or more selected from the group consisting of Ti, V, Cr, Mn, Fe, Co, Ni, Cu, Zn, Ga, Al, Nb, Mo, Cd, In, Sn, Sb, Ta and W.
